(19) United States
(12) Patent Application Publication
(10) Pub. No.: US 2014/0353763 A1
(43) Pub. Date: Dec. 4, 2014

(54) SEMICONDUCTOR DEVICES INCLUDING FIN-FETS AND METHODS OF FABRICATING THE SAME

(71) Applicant: Samsung Electronics Co., Ltd., Suwon-si (KR)

(72) Inventors: Jae-Yup Chung, Yongin-si (KR); Hee-Soo Kang, Seoul (KR); Soo-Hun Hong, Gunpo-si (KR)

(73) Assignee: Samsung Electronics Co., Ltd., Suwon-si (KR)

(21) Appl. No.: 14/287,322

(22) Filed: May 27, 2014

(30) Foreign Application Priority Data
Jun. 3, 2013 (KR) 10-2013-0063573

(51) Int. Cl. H01L 27/088

(52) U.S. Cl. CPC H01L 27/0886
USPC 257/390

(57) ABSTRACT

Semiconductor devices including fin-FETs and methods of forming the semiconductor devices are provided. The semiconductor devices may include a fin structure including a long side and a short side on a substrate, a first trench including a sidewall defined by the long side of the fin structure and a first field insulating layer in the first trench. The semiconductor devices may also include a second trench including a sidewall defined by the short side of the fin structure and a second field insulating layer in the second trench. A first distance between an uppermost surface of the fin structure and a lowermost surface of the first trench may be different from a second distance between the uppermost surface of the fin structure and a lowermost surface of the second trench.

### CROSS-REFERENCE TO RELATED APPLICATION

This U.S. non-provisional application claims priority under 35 U.S.C. §119 to Korean Patent Application No. 10-2013-0063573 filed on Jun. 3, 2013, in the Korean Intellectual Property Office, the disclosure of which is incorporated herein by reference in its entirety.

### FIELD

The present disclosure generally relates to the field of electronics and, more particularly, to semiconductor devices.

### BACKGROUND

A multi-gate transistor including a fin-shaped silicon body on a substrate and gates on the surface of the silicon body may be used to increase a density of a semiconductor device. Multi-gate transistors use three-dimensional (3D) channels, which may beneficial for scaling down. In addition, the current control capability of multi-gate transistors may be improved without increasing the gate length, which may help reduce a short channel effect (SCE).

### SUMMARY

A semiconductor device may include a fin structure including a long side and a short side on a substrate. The short side is perpendicular to the long side. The device may also include a first trench including a sidewall defined by the long side of the fin structure, a first field insulating layer in the first trench, a second trench including a sidewall defined by the short side of the fin structure and a second field insulating layer in the second trench. A first distance between an uppermost surface of the fin structure and a lowermost surface of the first trench may be different from a second distance between the uppermost surface of the fin structure and a lowermost surface of the second trench.

According to various embodiments, the second distance may be smaller than the first distance.

According to various embodiments, an uppermost surface of the second field insulating layer may be higher than the uppermost surface of the fin structure relative to the lowermost surface of the first trench.

According to various embodiments, the device may further include a dummy gate overlying an uppermost surface of the second field insulating layer.

In some embodiments, a first width of the dummy gate may be smaller than a second width of the uppermost surface of the second field insulating layer.

According to various embodiments, the second field insulating layer may include a first insulating layer on the sidewall of the second trench and the lowermost surface of the second trench and a second insulating layer on the first insulating layer in the second trench, and the second insulating layer may include a material different from the first insulating layer.

According to various embodiments, the second field insulating layer may include an insulating material different from the first field insulating layer.

In some embodiments, the device may further include a third trench and a third field insulating layer in the third trench, and the fin structure may in an active area defined by the third field insulating layer, and a third distance between the uppermost surface of the fin structure and a lowermost surface of the third trench may be greater than the first distance.

According to various embodiments, an uppermost surface of the third field insulating layer may be higher than the uppermost surface of the fin structure relative to the lowermost surface of the first trench.

According to various embodiments, the uppermost surface of the third field insulating layer and an uppermost surface of the second field insulating layer may be coplanar.

A semiconductor device may include a first fin structure including a first long side and a first short side on a substrate and the first long side is perpendicular to the first short side. The device may also include a second fin structure including a second long side facing the first long side and a second short side that is perpendicular to the second long side and a third fin structure including a third short side facing the first short side and a third long side that is perpendicular to the third short side. The device may further include a first trench including respective sidewalls defined by the first long side and the second long side and a second trench including respective sidewalls defined by the first short side and the third short side. A first distance between an uppermost surface of the first fin structure and a lowermost surface of the first trench may be different from a second distance between the uppermost surface of the first fin structure and a lowermost surface of the second trench.

According to various embodiments, the second distance may be smaller than the first distance.

In some embodiments, the device may further include a first field insulating layer in the first trench and a second field insulating layer in the second trench.

According to various embodiments, an uppermost surface of the second field insulating layer may be higher than the uppermost surface of the first fin structure relative to the lowermost surface of the first trench.

According to various embodiments, the device may further include a first gate on the first and second fin structures a second gate on the third fin structure, and a dummy gate on the second field insulating layer. An uppermost surface of the dummy gate and uppermost surfaces of the first and second gates may be coplanar.

An integrated circuit device may include a fin-shaped region protruding from an upper surface of a substrate and a recess in the fin-shaped region. A first distance between an uppermost surface of the fin-shaped region and a lowermost surface of the recess may be smaller than a second distance between the uppermost surface of the fin-shaped region and the upper surface of the substrate. The device may also include an insulating pattern in the recess, a first gate structure overlying the uppermost surface of the fin-shaped region and a second gate structure overlying an uppermost surface of the insulating pattern.

According to various embodiments, the uppermost surface of the insulating pattern may be higher than the uppermost surface of the fin-shaped region relative to the upper surface of the substrate.

In some embodiments, uppermost surfaces of the first and second gate structures may be coplanar.

In some embodiments, the device may further include a source/drain region between the first and second gate structures.

According to various embodiments, the source/drain region may include a stress inducing pattern having a lattice constant different from a lattice constant of the substrate, and an uppermost surface of the stress inducing pattern may be higher than the uppermost surface of the fin-shaped region relative to the upper surface of the substrate.

### BRIEF DESCRIPTION OF THE DRAWINGS

FIGS. 1 and 2 are plan and perspective views of a semiconductor device 1 according to some embodiments of the present inventive concepts.

FIG. 3A is a perspective view of the semiconductor device 1 of FIGS. 1 and 2 showing fins F1 and F2 and a field insulating layer 110.

FIG. 3B is a perspective view of the semiconductor device 1 of FIGS. 1 and 2 showing the fins F1 and F2, a first trench 501 and a second trench 501.

FIG. 4 is a cross-sectional view taken along the line A-A′ of FIG. 2.

FIG. 5 is a cross-sectional view taken along the line B-B′ of FIG. 2.

FIG. 6 is a cross-sectional view of a semiconductor device 2 according to some embodiments of the present inventive concepts.

FIG. 7 is a cross-sectional view of a semiconductor device 3 according to some embodiments of the present inventive concepts.

FIG. 8 is a cross-sectional view of a semiconductor device 4 according to some embodiments of the present inventive concepts.

FIG. 9 is a plan view of a semiconductor device 5 according to some embodiments of the present inventive concepts.

FIG. 10 is a cross-sectional view taken along the line A1-A1′ of FIG. 9.

FIG. 11 is a cross-sectional view taken along the line B1-B1′ of FIG. 9.

FIG. 12 is a block diagram of a semiconductor device 6 according to some embodiments of the present inventive concepts.

FIG. 13 is a block diagram of a semiconductor device 7 according to some embodiments of the present inventive concepts.

FIG. 14 is a block diagram of an electronic system 1100 including a semiconductor device according to some embodiments of the present inventive concepts.

FIGS. 15 through 29 are plan and cross-sectional views illustrating intermediate structures provided in operations of fabricating the semiconductor device 5 according to some embodiments of the present inventive concepts.

### DETAILED DESCRIPTION

Example embodiments are described below with reference to the accompanying drawings. The present inventive concepts may, however, be embodied in many different forms and should not be construed as being limited to the embodiments set forth herein. Rather, these example embodiments are provided so that this disclosure will be thorough and complete and will fully convey the concepts of the inventive concepts to those skilled in the art. In the drawings, the sizes and relative sizes of layers and regions may be exaggerated for clarity. Like reference numerals refer to like elements throughout the specification.

The terminology used herein is for the purpose of describing particular embodiments only and is not intended to be limiting of the present inventive concepts. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on”, “directly connected to” or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concepts.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Embodiments are described herein with reference to plan, perspective and cross-sectional illustrations that are schematic illustrations of idealized embodiments and intermediate structures. As such, variations from the shapes of the illustrations as a result, for example, of manufacturing techniques and/or tolerances, are to be expected. Thus, these embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concepts.

Unless otherwise defined, all terms (including technical and scientific terms) used herein have the same meaning as commonly understood by one of ordinary skill in the art to which the present inventive concepts belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

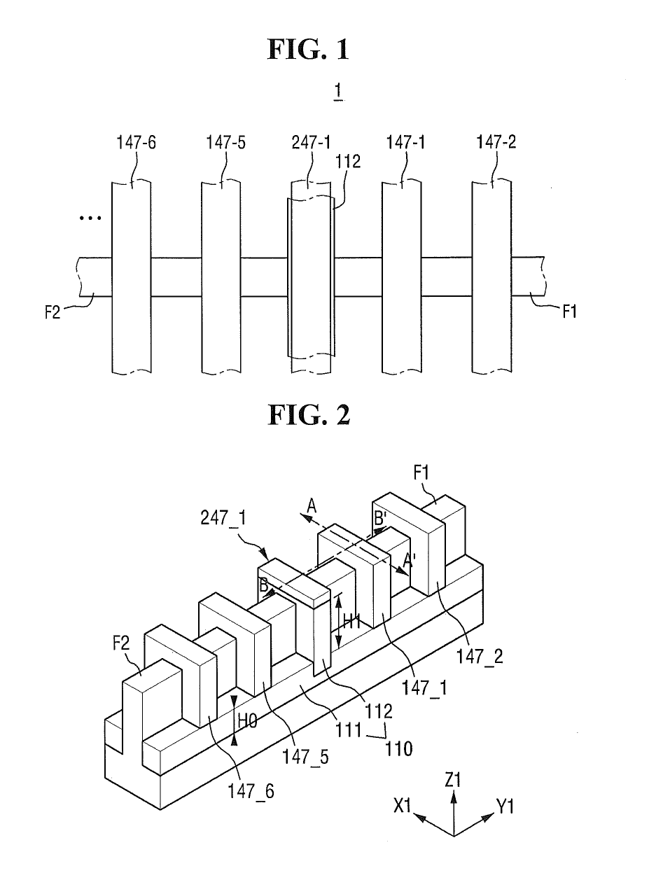

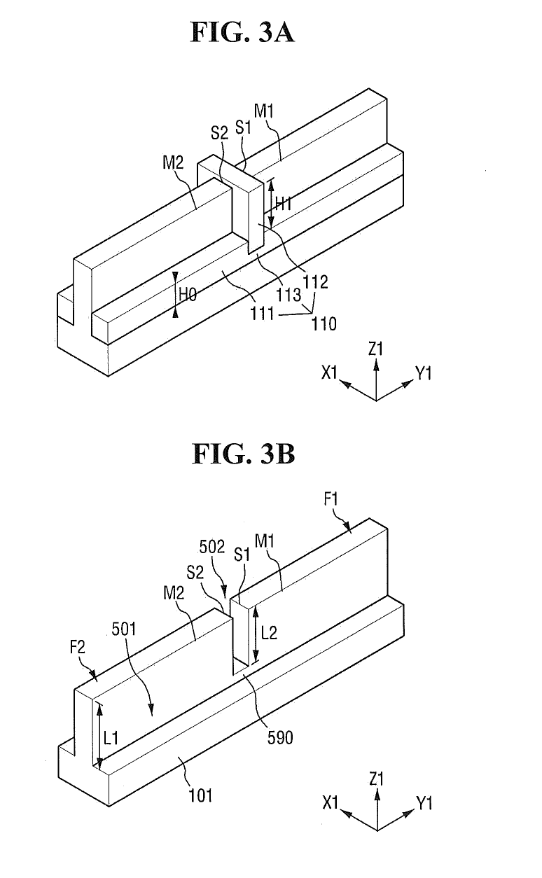

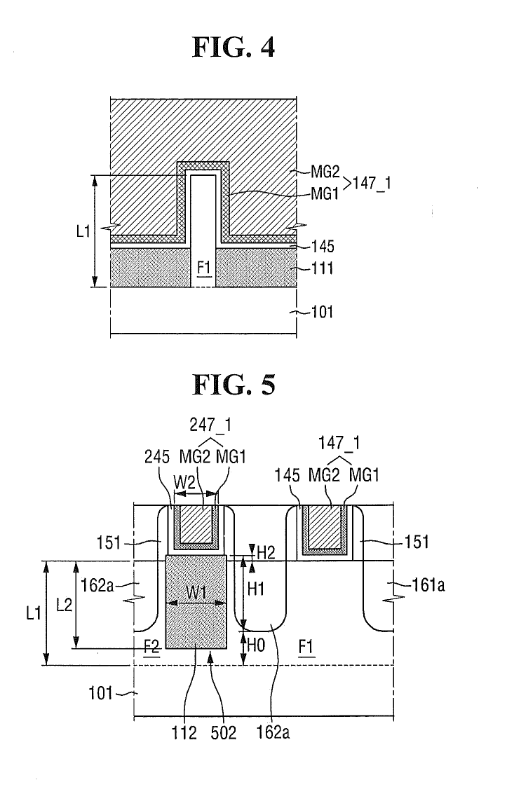

FIGS. 1 and 2 are plan and perspective views of a semiconductor device 1 according to some embodiments of the present inventive concepts. FIG. 3A is a perspective view of the semiconductor device 1 of FIGS. 1 and 2 showing fins F1 and F2 and a field insulating layer 110. FIG. 3B is a perspective view of the semiconductor device 1 of FIGS. 1 and 2 showing the fins F1 and F2, a first trench 501 and a second trench 501. FIG. 4 is a cross-sectional view taken along the line A-A′ of FIG. 2. FIG. 5 is a cross-sectional view taken along the line B-B′ of FIG. 2.

Referring to FIGS. 1 through 5, the semiconductor device 1 according to the some embodiments of the present inventive concepts may include the fins F1 and F2, the normal gates 147_1, 147_2, 147_5 and 147_6, the field insulating layer 110, the dummy gate 247_1, and a plurality of source/drain regions 161a and 162a.

The fins F1 and F2 may extend along a second direction Y1. The fins F1 and F2 may be part of a substrate 101 or may include an epitaxial layer grown from the substrate 101. In the drawings, two fins F1 and F2 extend side by side along a lengthwise direction, but the present inventive concepts are not limited thereto.

As illustrated in the drawings, the fins F1 and F2 may have rectangular parallelepiped shape. However, the shapes of the fins F1 and F2 are not limited thereto. In some embodiments, the fins F1 and F2 may be beveled, in other words, edges of the fins F1 and F2 may be rounded. Since the fins F1 and F2 extend along the second direction Y1, the fins F1 and F2 may include long sides M1 and M2 extending along the second direction Y1 and short sides S1 and S2 extending along a first direction X1. Specifically, a first fin F1 may include a first short side S1 and a first long side M1, and a second fin F2 may include a second short side S2 and a second long side M2. As shown in the drawings, the fins F1 and F2 may be formed such that the first short side S1 faces the second short side S2. In some embodiments, the edges of the fins F1 and F2 may be rounded and still may include the long sides M1 and M2 and the short sides S1 and S2.

The fins F1 and F2 may be active patterns of a multi-gate transistor. That is, a channel may be formed along three surfaces of each of the fins F1 and F2 or two opposing surfaces of each of the fins F1 and F2.

In addition, referring to FIG. 3B, the first trench 501 may include the long sides M1 and M2 of the fins F1 and F2 as sidewalls, and the second trench 502 may include the short sides S1 and S2 of the fins F1 and F2 as sidewalls. Specifically, the second trench 502 may include the short side S1 of the first fin F1 and the short side S2 of the second fin F2 that faces the short side S1 of the first fin F1.

A first length L1 from top surfaces (for example, uppermost surfaces) of the fins F1 and F2 to a bottom surface (for example, a lowermost surface) of the first trench 501 may be different from a second length L2 from the top surfaces of the fins F1 and F2 to a bottom surface of the second trench 502. That is, a depth of the first trench 501 may be different from a depth of the second trench 502.

As discussed herein, the depth of the first trench 501 may be different from the depth of the second trench 502 because an etching process for forming the first trench 501 may be performed separately from an etching process for forming the second trench 502. In addition, a first mask used to form the first trench 501 may be different from a second mask used to form the second trench 502.

In some embodiments, the second length L2 of the second trench 502 may be smaller than the first length L1 of the first trench 501. In this case, a connecting portion 590 which protrudes from the substrate 101 may be formed between the first fin F1 and the second fin F2. The connecting portion 590 may connect a lower portion of the first fin F1 and a lower portion of the second fin F2 together.

Referring to FIG. 3A, the field insulating layer 110 may be formed on the substrate 101 to partially surround the fins F1 and F2.

Specifically, the field insulating layer 110 may include a first field insulating layer 111 and a second field insulating layer 112 which have different heights relative to the bottom surface of the first trench 501. The first field insulating layer 111 may be formed, at least partially, in the first trench 501, and the second field insulating layer 112 may be formed, at least partially, in the second trench 502. In other words, the first field insulating layer 111 may be formed to contact the long sides M1 and M2 of the fins F1 and F2, and the second field insulating layer 112 may be formed to contact the short sides S1 and S2 of the fins F1 and F2.

The first field insulating layer 111 may be formed in only a portion of the first trench 501, and the second field insulating layer 112 may completely fill the second trench 502. Furthermore, a top surface of the second field insulating layer 112 may be higher than the top surfaces of the fins F1 and F2 relative to the bottom surface of the first trench 501. A height of the first field insulating layer 111 may be H0, and a height of the second field insulating layer 112 may be H0+H1.

The first field insulating layer 111 may extend along the second direction Y1, and the second field insulating layer 112 may extend along the first direction X1. In addition, a portion 113 of the first field insulating layer 111 may be disposed under the second field insulating layer 112. The field insulating layer 110 may be an oxide layer, a nitride layer, an oxynitride layer, or a combination of these layers.

The second field insulating layer 112 may be formed under the dummy gate 247_1, and the first field insulating layer 111 may be formed under the normal gates 147_1, 147_2, 147_5 and 147_6.

The normal gates 147_1, 147_2, 147_5 and 147_6 may be formed on the fins F1 and F2 and cross over the corresponding fins F1 and F2. In some embodiments, first and second normal gates 147_1 and 147_2 may be formed on the first fin F1, and fifth and sixth normal gates 147_5 and 147_6 may be formed on the second fin F2. These normal gates 147_1, 147_2, 147_5 and 147_6 may extend along the first direction X1.

The dummy gate 247_1 may be formed on the second field insulating layer 112. In particular, only one dummy gate 247_1 may be formed on the second field insulating layer 112. Since only one dummy gate 247_1 is formed on the second field insulating layer 112, the layout size may be reduced. In addition, a width W2 of the dummy gate 247_1 may be smaller than a width W1 of the second field insulating layer 112. Accordingly, the dummy gate 247_1 can be disposed on the second field insulating layer 112.

Referring to FIGS. 4 and 5, each normal gate (e.g., 147_1) may include metal layers MG1 and MG2. The normal gate 147_1 may include a stack of two or more metal layers MG1 and MG2. A first metal layer MG1 may adjust a work function, and a second metal layer MG2 may fill a space defined by the first metal layer MG1. In some embodiments, the first metal layer MG1 may include at least one of TiN, TaN, TiC and TaC, and the second metal layer MG2 may include W or Al. The normal gate 147_1 may be formed by, but not limited to, a replacement process (or a gate last process).

The dummy gate 247_1 may have a similar structure to the structure of the normal gate 147_1. The dummy gate 247_1 may include a stack of two or more metal layers MG1 and MG2. A first metal layer MG1 may adjust a work function, and a second metal layer MG2 may fill a space formed by the first metal layer MG1.

A gate insulating layer 145 may be formed between the first fin F1 and the normal gate 147_1. As shown in FIG. 4, the gate insulating layer 145 may be formed on top and side surfaces of the first fin F1. Also, the gate insulating layer 145 may be formed between the normal gate 147_1 and the first field insulating layer 111. The gate insulating layer 145 may include a high dielectric material having a dielectric constant higher than a dielectric constant of a silicon oxide layer. For example, the gate insulating layer 145 may include HfO2, ZrO2, or Ta2O5.

The source/drain regions 161a and 162a may be disposed between two of the normal gates 147_1, 147_2, 147_5 and 147_6 and between a normal gate (e.g., 147_1) and the dummy gate 247_1. The source/drain regions 161a and 162a shown in the drawings may be formed by doping the fins F1 and F2 with impurities, but the present inventive concepts are not limited thereto.

Spacers 151 may include at least one of a nitride layer and an oxynitride layer. The spacers 151 may be formed on sidewalls of the fins F1 and F2, the normal gates 147_1, 147_2, 147_5 and 147_6, and the dummy gate 247_1.

The substrate 101 may be formed of one or more semiconductor materials selected from the group consisting of Si, Ge, SiGe, GaP, GaAs, SiC, SiGeC, InAs, and InP. In addition, a silicon-on-insulator (SOI) substrate may be used.

Referring to FIGS. 2 and 5, the first field insulating layer 111 and the second field insulating layer 112 of the field insulating layer 110 have different vertical thicknesses. The vertical thickness of the first field insulating layer 111 may be smaller than the vertical thickness of the second field insulating layer 112. A height of the first field insulating layer 111 may be H0, and a height of the second field insulating layer 112 may be H0+H1.

At least a portion of an upper surface of the field insulating layer 110 (i.e., the top surface of the second field insulating layer 112) may be higher than bottom surfaces of the normal gates 147_1 147_2 147_5 and 147_6 relative to the bottom surface of the first trench 501. The normal gates 147_1, 147_2, 147_5 and 147_6 may be formed on the top surface of the first field insulating layer 111 and the top and side surfaces of the fins F1 and F2. The bottom surfaces of the normal gates 147_1, 147_2, 147_5 and 147_6 are the lowermost surfaces of the normal gates 147_1, 147_2, 147_5 and 147_6. In FIG. 2, surfaces of the normal gates 147_1, 147_2, 147_5 and 147_6 which contact the top surface of the first field insulating layer 111 may be the bottom surfaces.

In addition, the top surface of the second field insulating layer 112 may be at the same height as top surfaces of the source/drain regions 161a and 162a or may be higher than the top surfaces of the source/drain regions 161a and 162a relative to the bottom surface of the first trench 501. In other words, the top surface of the second field insulating layer 112 may be at the same level as the top surfaces of the fins F1 and F2 or may be higher than the top surfaces of the fins F1 and F2 relative to the bottom surface of the first trench 501. As illustrated in the drawings, the top surface of the second field insulating layer 112 may be higher than the top surfaces of the fins F1 and F2 by H2 relative to the bottom surface of the first trench 501.

Accordingly, a vertical thickness of the dummy gate 247_1 may be different from vertical thicknesses of the normal gates 147_1, 147_2, 147_5 and 147_6 (e.g., as illustrated in FIG. 5.). A top surface of the dummy gate 247_1 may be at the same height as (e.g., coplanar with) top surfaces of the normal gates 147_1, 147_2, 147_5 and 147_6 relative to the bottom surface of the first trench 501. In some embodiments, the dummy gate 247_1 and the normal gates 147_1, 147_2, 147_5 and 147_6 may be formed by a planarization process, and their top surfaces may thus be at the same height relative to the bottom surface of the first trench 501. Therefore, if the top surface of the second field insulating layer 112 is higher than the top surfaces of the fins F1 and F2 relative to the bottom surface of the first trench 501, a vertical thickness of the dummy gate 247_1 may be smaller/thinner than the vertical thicknesses of the normal gates 147_1, 147_2, 147_5 and 147_6 when viewed in a cross section because the dummy gate 247_1 is formed on the second field insulating layer 112, and the normal gates 147_1, 147_2, 147_5 and 147_6 are formed on the fins F1 and F2.

The above configuration may be implemented for the reasons discussed herein. In the semiconductor device 1, the dummy gate 247_1 may be not disposed between the first fin F1 and the second fin F2 because the top surface of the second field insulating layer 112 is at the same height as or higher than the top surfaces of the fins F1 and F2. Therefore, a first parasitic capacitance between the dummy gate 247_1 and the first fin F1 and a second parasitic capacitance between the dummy gate 247_1 and the second fin F2 may be very small. In addition, since the dummy gate 247_1 may not contact the first fin F1 and the second fin F2, the amount of leakage current may be very small.

The reason that the first trench 501 and the second trench 502 may be formed by separate etching processes using separate masks is discussed herein. Similarly, the reason that the first field insulating layer 111 and the second field insulating layer 112 may be formed separately is discussed herein.

As described above, the sizes of the first and second parasitic capacitances and the amount of leakage current may vary according to a height of the second field insulating layer 112 relative to the bottom surface of the first trench 501. If the second trench 502 is formed by a separate etching process using a separate mask, then the height of the second field insulating layer 112 formed in the second trench 502 may be easily adjusted as desired.

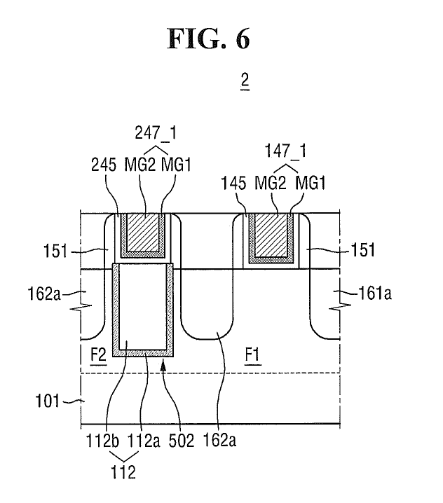

FIG. 6 is a cross-sectional view of a semiconductor device 2 according to some embodiments of the present inventive concepts. Referring to FIG. 6, a second field insulating layer 112 may include a first insulating layer 112a which is formed along sidewalls and a bottom surface of a second trench 502 and a second insulating layer 112b which is formed on the first insulating layer 112a in the second trench 502. The second insulating layer 112b may be formed to completely fill the second trench 502. The second insulating layer 112b may include a material different from materials that the first insulating layer 112a includes. For example, the first insulating layer 112a may be a nitride layer, and the second insulating layer 112b may be an oxide layer.

In some embodiments, insulating materials included in a first field insulating layer 111 and insulating materials included in the second field insulating layer 112 may be different. In some embodiments, the first field insulating layer 111 may be formed of a plurality of insulating materials, and the second field insulating layer 112 may be formed of a plurality of insulating materials. At least one among the plurality of insulating materials included in the second field insulating layer 112 may not be included in the first field insulating layer 111. In some embodiments, the second field insulating layer 112 may include a nitride layer (i.e., the first insulating layer 112a) and an oxide layer (i.e., the second insulating layer 112b), and the first field insulating layer 111 may include an oxide layer. That is, the first field insulating layer 111 may not include a nitride layer.

The insulating materials included in the first field insulating layer 111 may be different from the insulating materials included in the second field insulating layer 112 because the first field insulating layer 111 and the second field insulating layer 112 may be formed by separate processes.

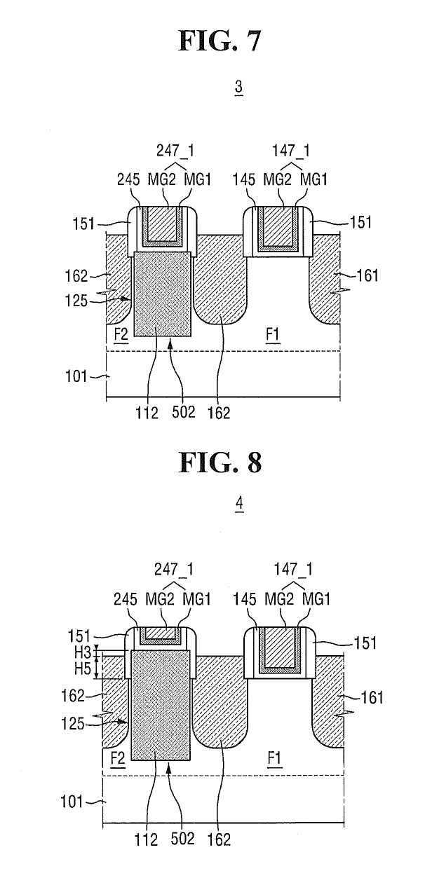

FIG. 7 is a cross-sectional view of a semiconductor device 3 according to some embodiments of the present inventive concepts. Referring to FIG. 7, recesses 125 may be formed between a plurality of normal gates 147_1, 1472, 147_5 and 147_6 and within fins F1 and F2 between the normal gates 147_1, 147_2, 147_5 and 147_6 and a dummy gate 247_1. Source/drain regions 161 and 162 may be formed in the recesses 125. The source/drain regions 161 and 162 may include an epitaxial layer. That is, the source/drain regions 161 and 162 may be formed by epitaxial growth. In addition, the source/drain regions 161 and 162 may be elevated source/drain regions having top surfaces higher than top surfaces of the fins F1 and F2.

In addition, as shown in the drawing, the source/drain regions 161 and 162 may be formed to partially undercut spacers 151. That is, part of the source/drain regions 161 and 162 may be tucked under the spacers 151.

A height of the source/drain regions 161 disposed between the normal gates 147_1, 147_2, 147_5 and 147_6 may be equal to or substantially equal to a height of the source/drain regions 162 disposed between the normal gates 147_1, 147_2, 147_5 and 147_6 and the dummy gate 247_1. The heights of the source/drain regions 161 and 162 may be the heights of those relative to the bottom surface of the first trench 501. Here, the heights of the source/drain regions 161, 162 may vary as a result, for example, of manufacturing techniques and/or tolerances. Accordingly, the heights of the source/drain regions 161, 162 may be substantially equal to each other rather than exactly equal to each other. That means, the source/drain regions 162 between the normal gates 147_1, 147_2, 147_5 and 147_6 and the dummy gate 247_1 may be grown sufficiently to have uppermost surfaces coplanar with upper surfaces of the source/drain regions 161.

The semiconductor device 3 may be a P-type metal-oxide-semiconductor (PMOS) transistor, and the source/drain regions 161 and 162 may thus include a compressive stress material. For example, the compressive stress material may be a material having a lattice constant greater than a lattice constant of Si, such as SiGe. The compressive stress material may improve the mobility of carriers in a channel region by applying compressive stress to a first fin F1.

Alternatively, the semiconductor device 3 may be an N-type metal-oxide-semiconductor (NMOS) transistor, and the source/drain regions 161 and 162 may thus include the same material as a substrate 101 or a tensile stress material. For example, in a case in which the substrate 101 includes Si, the source/drain regions 161 and 162 may include Si or a material, such as SiC, having a lattice constant smaller than a lattice constant of Si.

FIG. 8 is a cross-sectional view of a semiconductor device 4 according to some embodiments of the present inventive concepts. Referring to FIG. 8, source/drain regions 161 and 162 may be elevated source/drain regions. Top surfaces of the source/drain regions 161 and 162 may be higher than top surfaces of the fins F1 and F2 by a height of H5 relative to the bottom surface of the first trench 501. In addition, the source/drain regions 161 and 162 may be insulated from a normal gate 147_1 by spacers 151.

In the semiconductor device 4, a top surface of a second field insulating layer 112 may be at the same height as the top surfaces of the elevated source/drain regions 161 and 162 or may be higher than the top surfaces of the elevated source/drain regions 161 and 162 relative to the bottom surface of the first trench 501. As illustrated in the drawing, the top surface of the second field insulating layer 112 may be higher than the top surfaces of the elevated source/drain regions 161 and 162 by a height of H3 relative to the bottom surface of the first trench 501. Therefore, a parasitic capacitance formed between a dummy gate 247_1 and the elevated source/drain regions 162 may be very small. In addition, since the dummy gate 247_1 may not contact the elevated source/drain regions 162, the amount of leakage current may be very small.

A vertical thickness of the dummy gate 247_1 may be different from vertical thicknesses of normal gates 147_1, 147_2, 147_5 and 147_6. The vertical thickness of the dummy gate 247_1 may be smaller than the vertical thicknesses of the normal gates 147_1, 147_2, 147_5 and 147_6.

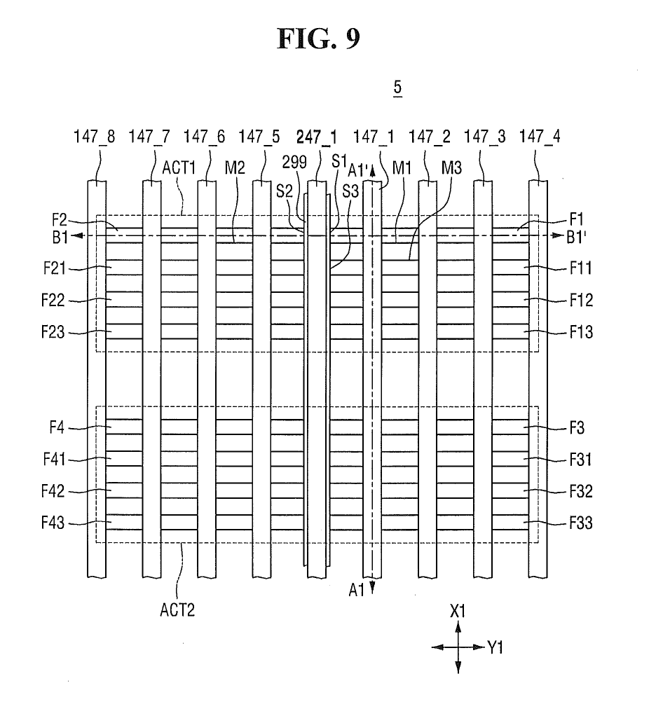

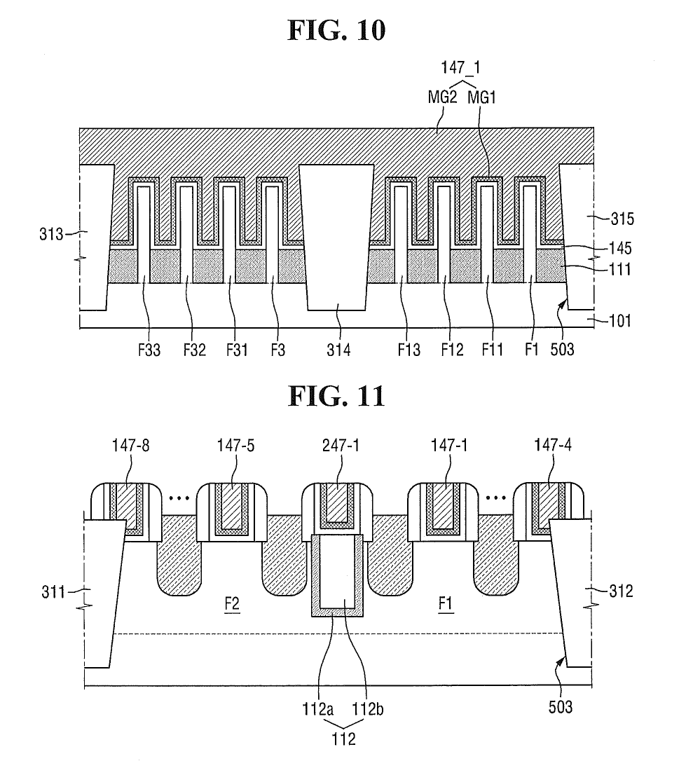

FIG. 9 is a plan view of a semiconductor device 5 according to some embodiments of the present inventive concepts. FIG. 10 is a cross-sectional view taken along the line A1-A1′ of FIG. 9, and FIG. 11 is a cross-sectional view taken along the line B1-B1′ of FIG. 9. Referring to FIGS. 9 through 11, the semiconductor device 5 may include a plurality of fins F1 through F13, F2 through F23, F3 through F33 and F4 through F43, a plurality of normal gates 147_1 through 147_8, a dummy gate 247_1, a first field insulating layer 111, a second field insulating layer 112, third field insulating layers 311 through 315, a first active area ACT1, and a second active area ACT2.

The fins F1 through F13 and the fins F2 through F23 may be formed within the first active area ACT1, and the fins F3 through F33 and the fins F4 through F43 may be formed within the second active area ACT2. As shown in the drawings, the first active area ACT1 and the second active area ACT2 may be defined by the third field insulating layers 311 through 315. The third field insulating layers 311 through 315 may have deep trench shape and may include, but are not limited to, an oxide layer. In addition, top surfaces of the third field insulating layers 311 through 315 may be higher than top surfaces of the fins F1 through F13, F2 through F23, F3 through F33 and F4 through F43.

The fins F1 through F13, F2 through F23, F3 through F33 and F4 through F43 may extend along a second direction Y1. Specifically, short sides of the fins F1 through F13 may face respective short sides of the fins F2 through F23, and short sides of the fins F3 through F33 may face respective short sides of the fins F4 through F43. Also, long sides of the fins F1 through F13 and long sides of the fins F3 through F33 may extend in parallel, and long sides of the fins F2 through F23 and long sides of the fins F4 through F43 may extend in parallel.

The normal gates 147_1 through 147_4 may extend along a first direction X1 and overlap/cross over the fins F1 through F13 and F3 through F33. The normal gates 147_5 through 147_8 may extend along the first direction X1 and overlap/cross over the fins F2 through F23 and F4 through F43. Some (e.g., 147_4 and 147_8) of the normal gates 147_1 through 147_8 may be formed on the third field insulating layers 311 and 312, but the present inventive concepts are not limited thereto.

The second field insulating layer 112 may intersect the first active area ACT1 and the second active area ACT2. The second field insulating layer 112 may be disposed between the normal gate 147_1 and the normal gate 147_5. The dummy gate 247_1 may be disposed on the second field insulating layer 112. In some embodiments, only one dummy gate 247_1 may be formed on the second field insulating layer 112. Since only one dummy gate 247_1 is formed on the second field insulating layer 112, the layout size may be reduced. The second field insulating layer 112 may have a shallow trench shape and may be shallower than the third field insulating layers 311 through 315. In addition, the second field insulating layer 112 may include a first insulating layer 112a which is formed along sidewalls and a bottom surface of the trench and a second insulating layer 112b which is formed on the first insulating layer 112a in the trench. For example, the first insulating layer 112a may be a nitride layer, and the second insulating layer 112b may be an oxide layer.

The first field insulating layer 111, the second field insulating layer 112 and the third field insulating layers 311 through 315 may have different shapes (e.g., vertical thickness). A vertical thickness of the second field insulating layer 112 may be greater than a vertical thickness of the first field insulating layer 111, and vertical thicknesses of the third field insulating layers 311 through 315 may be greater than the vertical thickness the second field insulating layer 112.

In summary, a first fin F1 may include a first long side M1 and a first short side S1, a second fin F2 may include a second long side M2 and a second short side S2, and a third fin F11 may include a third long side M3 and a third short side S3. Here, the first short side S1 and the second short side S2 may face each other, and the first long side M1 and the third long side M3 may face each other. A first trench and the first field insulating layer 111 at least partially filling the first trench may be formed between the first long sides M1 and the third long sides M3. A second trench and the second field insulating layer 112 filling the second trench may be formed between the first short side S1 and the second short side S2. A first length L1 from a top surface of the first fin F1 to a bottom surface of the first trench may be different from a second length L2 from the top surface of the first fin F1 to a bottom surface of the second trench. The second length L2 may be smaller than the first length L1.

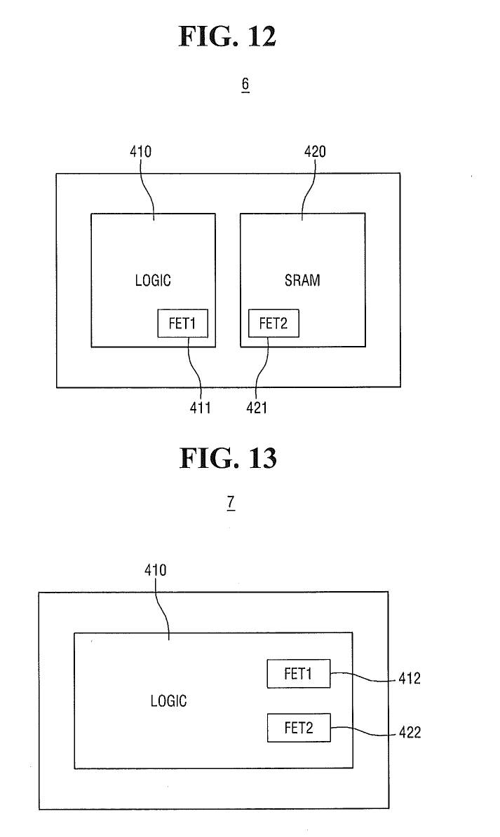

FIG. 12 is a block diagram of a semiconductor device 6 according to some embodiments of the present inventive concepts. FIG. 13 is a block diagram of a semiconductor device 7 according to some embodiments of the present inventive concepts.

Referring first to FIG. 12, in the semiconductor device 6, a multi-gate transistor 411 may be disposed in a logic area 410, and another multi-gate transistor 421 may be disposed in a static random access memory (SRAM) area 420. Referring to FIG. 13, in the semiconductor device 7, different multi-gate transistors 412 and 422 may be disposed in a logic area 410. Although not specifically shown, different multi-gate transistors may also be disposed in an SRAM area.

The multi-gate transistors 411 and 422 may be a semiconductor device according to some embodiments of the present inventive concepts. For example, the multi-gate transistor 411 may be the semiconductor device 1 of FIG. 5, and the multi-gate transistor 412 may be the semiconductor device 2 of FIG. 6. In some embodiments, the multi-gate transistor 411 may be the semiconductor device 3 of FIG. 7, and the multi-gate transistor 412 may be the semiconductor device 4 of FIG. 8.

In FIG. 12, the logic area 410 and the SRAM area 420 are illustrated as an example. However, the present inventive concepts are not limited to this example. The present inventive concepts are also applicable to the logic area 410 and an area in which another memory (e.g., DRAM, MRAM, RRAM, PRAM, etc.) is formed.

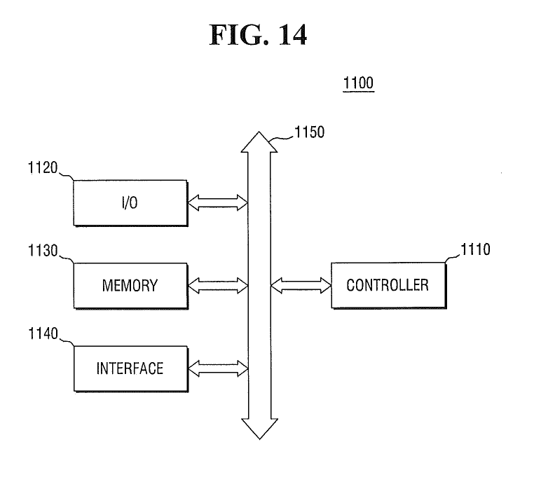

FIG. 14 is a block diagram of an electronic system 1100 including a semiconductor device according to some embodiments of the present inventive concepts. The electronic system 1100 of FIG. 14 is an exemplary system to which the semiconductor devices described above with reference to FIGS. 1 through 13 can be applied.

Referring to FIG. 14, the electronic system 1100 according to some embodiments of the present inventive concepts may include a controller 1110, an input/output (I/O) device 1120, a memory device 1130, an interface 1140 and a bus 1150. The controller 1110, the I/O device 1120, the memory device 1130 and/or the interface 1140 may be connected to one another by the bus 1150. The bus 1150 may serve as a path for transmitting data.

The controller 1110 may include at least one of a microprocessor, a digital signal processor, a microcontroller and logic devices capable of performing similar functions to those of a microprocessor, a digital signal processor and a microcontroller. The I/O device 1120 may include a keypad, a keyboard and a display device. The memory device 1130 may store data and/or commands. The interface 1140 may be used to transmit data to or receive data from a communication network. The interface 1140 may be a wired or wireless interface. For example, the interface 1140 may include an antenna or a wired or wireless transceiver. The electronic system 1100 may be an operating memory for improving the operation of the controller 1110, and may also include a high-speed dynamic random access memory (DRAM) or SRAM. Semiconductor devices according to some embodiments of the present inventive concepts may be provided in the memory device 1130 or in the controller 1110 or the I/O device 1120.

The electronic system 1100 may be applied to nearly all types of electronic products capable of transmitting or receiving information in a wireless environment, such as a personal digital assistant (PDA), a portable computer, a web tablet, a wireless phone, a mobile phone, a digital music player, a memory card, etc.

A method of fabricating the semiconductor device 5 according to the some embodiments of the present inventive concepts will now be described with reference to FIGS. 15 through 29 and 9 through 11.

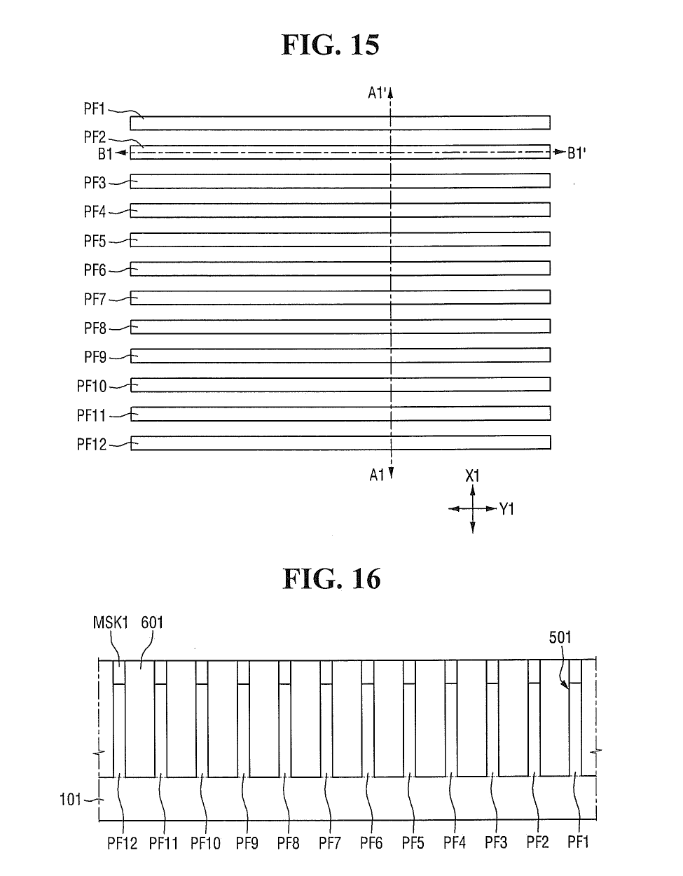

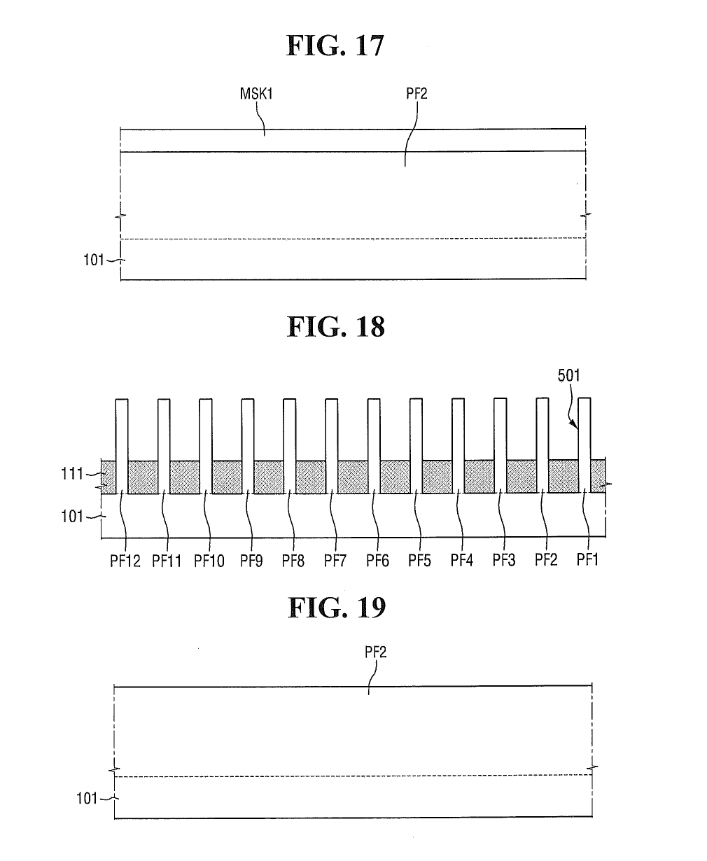

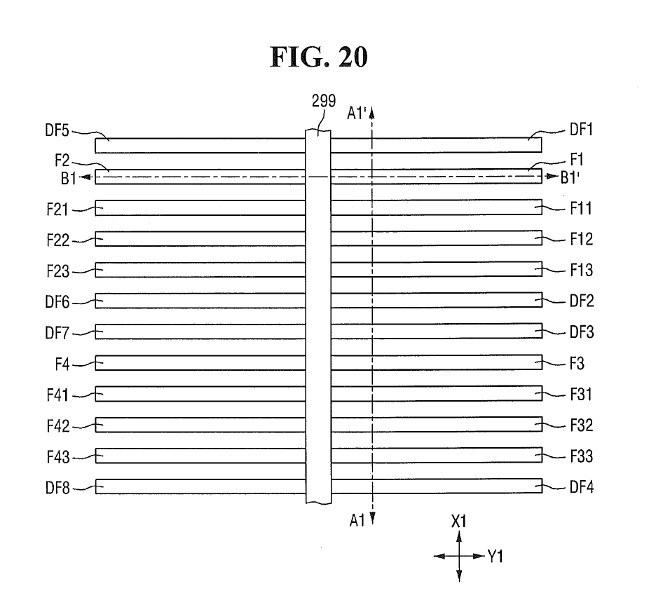

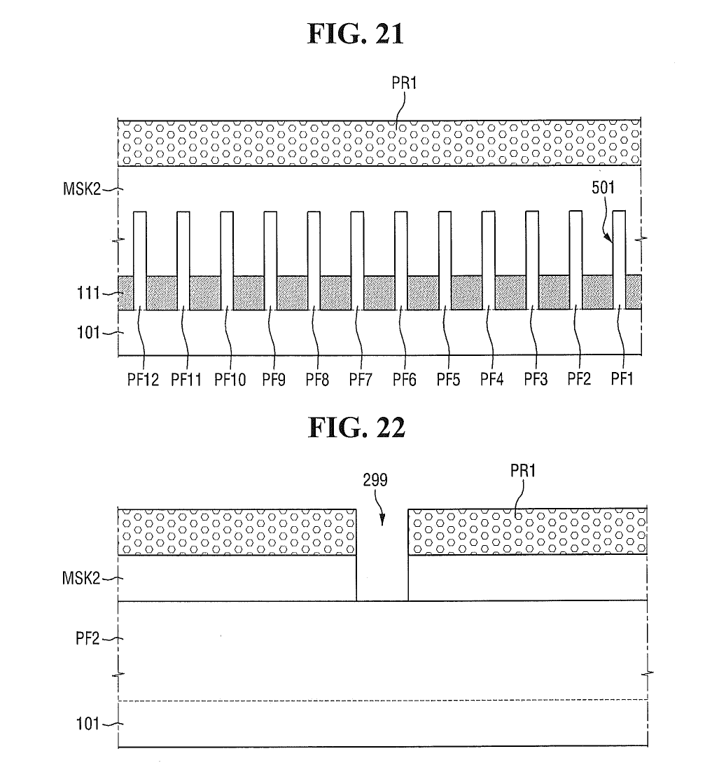

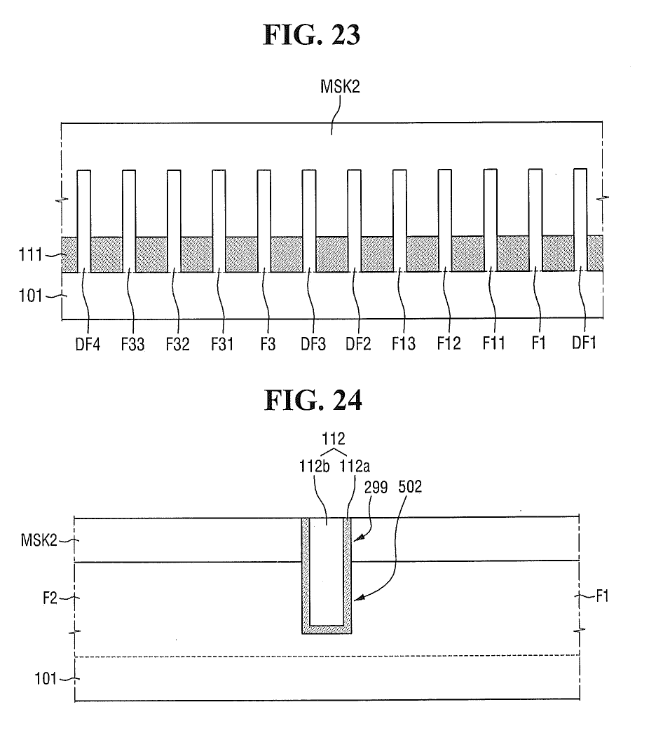

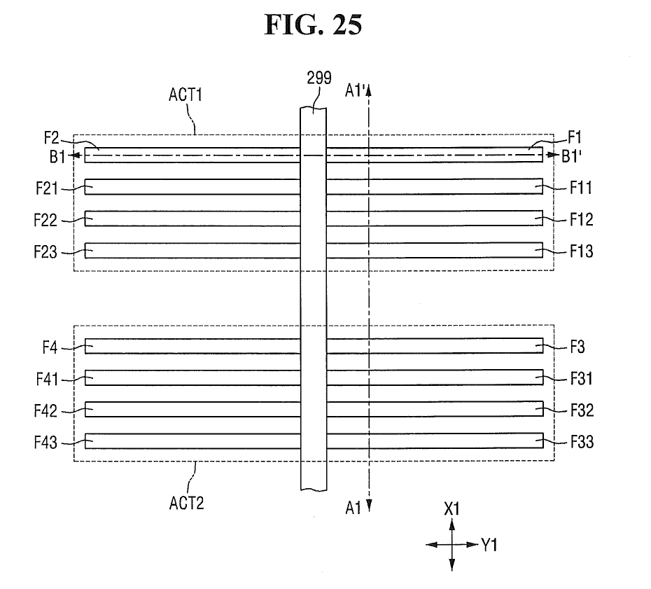

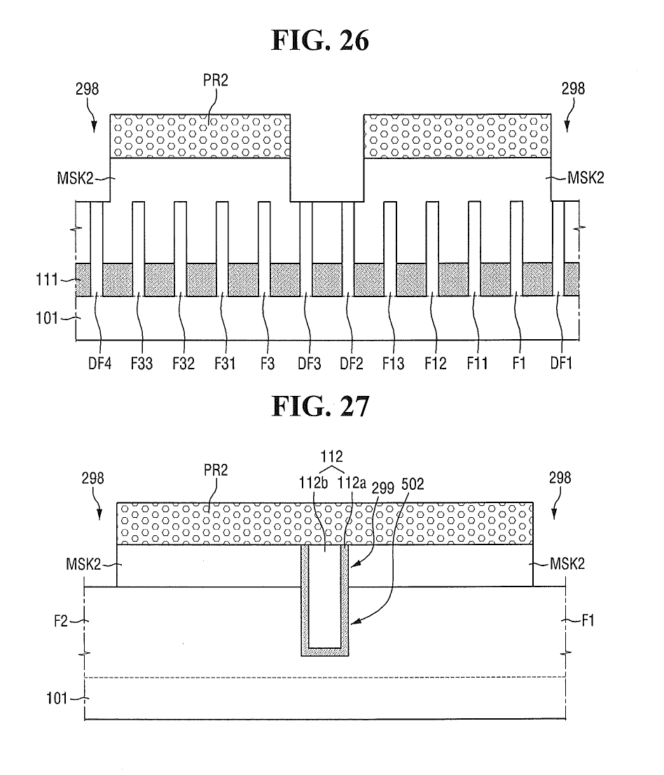

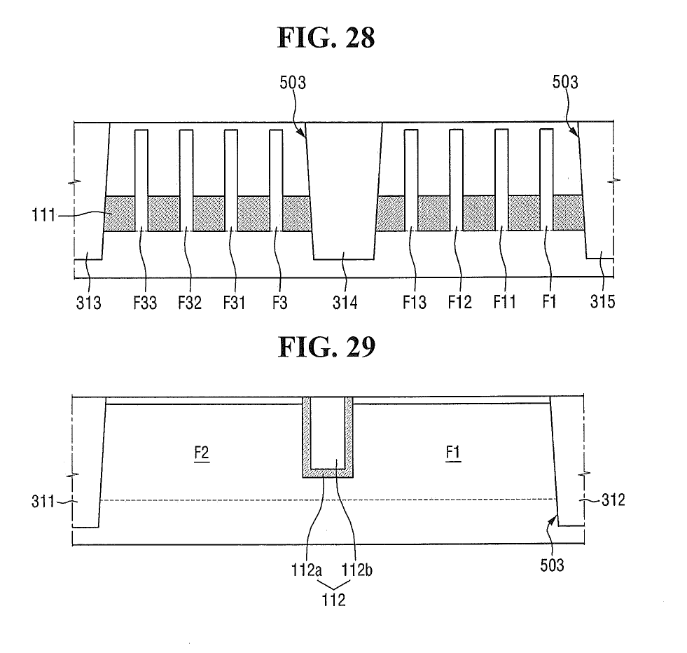

FIGS. 15 through 29 are plan and cross-sectional views illustrating intermediate structures provided in operations of fabricating the semiconductor device 5 according to the some embodiments of the present inventive concepts. Specifically, FIGS. 16 and 18 are cross-sectional views taken along the line A1-A1′ of FIG. 15, and FIGS. 17 and 19 are cross-sectional views taken along the line B1-B1′ of FIG. 15. FIGS. 21 and 23 are cross-sectional views taken along the line A1-A1′ of FIG. 20, and FIGS. 22 and 24 are cross-sectional views taken along the line B1-B1′ of FIG. 20. FIGS. 26 and 28 are cross-sectional views taken along the line A1-A1′ of FIG. 25, and FIGS. 27 and 29 are cross-sectional views taken along the line B1-B1′ of FIG. 25.

Referring to FIGS. 15 through 17, a plurality of preliminary fins PF1 through PF12 may be formed on a substrate 101. Specifically, a first mask MSK1 may be formed on the substrate 101. The substrate 101 may be etched using the first mask MSK1. As a result, first trenches 501 may be formed, and thereby the preliminary fins PF1 through PF12 may be formed. The preliminary fins PF1 through PF12 may extend along a second direction Y1.

A first preliminary insulating layer 601 may be formed between two adjacent ones among the preliminary fins PF1 through PF12. Specifically, an insulating layer may be formed to fill the first trenches 501 and may cover the preliminary fins PF1 through PF12. In some embodiments, the insulating layer may completely fill the first trenches 501. Then, the insulating layer may be planarized to expose top surfaces of the preliminary fins PF1 through PF12, and thereby the first preliminary insulating layer 601 may be formed.

Referring to FIGS. 18 and 19, the first preliminary insulating layer 601 may be recessed to form a first field insulating layer 111 around the preliminary fins PF1 through PF12. A top surface of the first field insulating layer 1,11 may be lower than the top surfaces of the preliminary fins PF1 through PF12. The first mask MSK1 may be removed.

Referring to FIGS. 20 through 22, a second mask MSK2 may be formed on the preliminary fins PF1 through PF12 and the first field insulating layer 111 to fill the first trenches 501. In some embodiments, the first field insulating layer 111 may completely fill the first trenches 501. For example, the second mask MSK2 may be a nitride layer.

A first photoresist pattern PR1 may be formed on the second mask MSK2. The second mask MSK2 may be patterned using the first photoresist pattern PR1. As a result, a first hole 299 may be formed in the second mask MSK2. As shown in FIG. 20, the first hole 299 may extend along a first direction X1 and overlap the preliminary fins PF1 through PF12.

Referring to FIGS. 23 and 24, the preliminary fins PF1 through PF12 may be etched using the second mask MSK2, thereby forming a second trench 502. The preliminary fins PF1 through PF12 may be divided into a plurality of fins F1 through F13, F2 through F23, F3 through F33, F4 through F43 and DF1 through DF8. The preliminary fin PF2 may be divided into a first fin F1 and a second fin F2 by the second trench 502 as shown in FIG. 24.

A second preliminary insulating layer may be formed to completely fill the second trench 502 and the first hole 299. That is, a nitride layer may be conformally formed, and an oxide layer may be formed on the nitride layer to fill the second trench 502 and the first hole 299. The second preliminary insulating layer (i.e., the nitride layer and the oxide layer) may be planarized to form a second field insulating layer 112 in the second trench 502 and the first hole 299.

Referring to FIGS. 25 through 27, a second photoresist pattern PR2 may be formed on the second mask MSK2. Then, the second mask MSK2 may be patterned using the second photoresist pattern PR2. As a result, a second hole 298 may be formed in the second mask MSK2. The second hole 298 may define an active area.

Referring to FIGS. 28 and 29, the fins DF1 through DF8 may be etched using the second mask MSK2, thereby forming third trenches 503. Here, the third trenches 503 may have deep trench shape and may be formed deeper than the second trench 502. In particular, the third trenches 503 may completely remove some fins DF1 through DF8.

The third trenches 503 may be filled with an insulating layer, and the insulating layer may be planarized to complete third field insulating layers 311 through 315. In some embodiments, the third trenches 503 may be completely filled with an insulating layer. In this planarization process, the second field insulating layer 112 may also be planarized. Accordingly, top surfaces of the third field insulating layers 311 through 315 may be at the same height as (e.g., may be coplanar with) a top surface of the second field insulating layer 112 relative to the bottom surface of the first trench 501.

Referring again to FIGS. 9 through 11, the second mask MSK2 may be removed. Then, a plurality of normal gates 147_1 through 147_8 may be formed to intersect the fins F1 through F13, F2 through F23, F3 through F33 and F4 through F43, and a dummy gate 247_1 may be formed on the second field insulating layer 112.

The foregoing description is illustrative of the present inventive concepts and is not to be construed as limiting thereof. Although some embodiments of the present inventive concepts have been described, those skilled in the art will readily appreciate that many modifications are possible in the embodiments without materially departing from the novel teachings and advantages of the present inventive concepts. Accordingly, all such modifications are intended to be included within the scope of the present inventive concepts as defined in the claims. Thus, to the maximum extent allowed by law, the scope is to be determined by the broadest permissible interpretation of the following claims and their equivalents, and shall not be restricted or limited by the foregoing detailed description. The present inventive concepts are defined by the following claims, with equivalents of the claims to be included therein.

What is claimed is:

1. A semiconductor device comprising:
a fin structure comprising a long side and a short side on a substrate, wherein the short side is perpendicular to the long side;
a first trench comprising a sidewall defined by the long side of the fin structure;
a first field insulating layer in the first trench;
a second trench comprising a sidewall defined by the short side of the fin structure; and
a second field insulating layer in the second trench,
wherein a first distance between an uppermost surface of the fin structure and a lowermost surface of the first trench is different from a second distance between the uppermost surface of the fin structure and a lowermost surface of the second trench.

2. The semiconductor device of claim 1, wherein the second distance is smaller than the first distance.

3. The semiconductor device of claim 1, wherein an uppermost surface of the second field insulating layer is higher than the uppermost surface of the fin structure relative to the lowermost surface of the first trench.

4. The semiconductor device of claim 1, further comprising a dummy gate overlying an uppermost surface of the second field insulating layer.

5. The semiconductor device of claim 4, wherein a first width of the dummy gate is smaller than a second width of the uppermost surface of the second field insulating layer.

6. The semiconductor device of claim 1, wherein the second field insulating layer comprises a first insulating layer on the sidewall of the second trench and the lowermost surface of the second trench and a second insulating layer on the first insulating layer in the second trench, and the second insulating layer comprises a material different from the first insulating layer.

7. The semiconductor device of claim 1, wherein the second field insulating layer comprises an insulating material different from the first field insulating layer.

8. The semiconductor device of claim 1, further comprising a third trench and a third field insulating layer in the third trench, wherein the fin structure is in an active area defined by the third field insulating layer, and a third distance between the uppermost surface of the fin structure and a lowermost surface of the third trench is greater than the first distance.

9. The semiconductor device of claim 8, wherein an uppermost surface of the third field insulating layer is higher than the uppermost surface of the fin structure relative to the lowermost surface of the first trench.

10. The semiconductor device of claim 9, wherein the uppermost surface of the third field insulating layer and an uppermost surface of the second field insulating layer are coplanar.

11. A semiconductor device comprising:
a first fin structure comprising a first long side and a first short side on a substrate, wherein the first long side is perpendicular to the first short side;
a second fin structure comprising a second long side facing the first long side and a second short side that is perpendicular to the second long side;
a third fin structure comprising a third short side facing the first short side and a third long side that is perpendicular to the third short side;
a first trench comprising respective sidewalls defined by the first long side and the second long side; and
a second trench comprising respective sidewalls defined by the first short side and the third short side,
wherein a first distance between an uppermost surface of the first fin structure and a lowermost surface of the first trench is different from a second distance between the uppermost surface of the first fin structure and a lowermost surface of the second trench.

12. The semiconductor device of claim 11, wherein the second distance is smaller than the first distance.

13. The semiconductor device of claim 11, further comprising:
a first field insulating layer in the first trench; and
a second field insulating layer in the second trench.

14. The semiconductor device of claim 13, wherein an uppermost surface of the second field insulating layer is higher than the uppermost surface of the first fin structure relative to the lowermost surface of the first trench.

15. The semiconductor device of claim 13, further comprising:
a first gate on the first and second fin structures;
a second gate on the third fin structure; and
a dummy gate on the second field insulating layer, wherein an uppermost surface of the dummy gate and uppermost surfaces of the first and second gates are coplanar.

16. An integrated circuit device, comprising:
a fin-shaped region protruding from an upper surface of a substrate;
a recess in the fin-shaped region, wherein a first distance between an uppermost surface of the fin-shaped region and a lowermost surface of the recess is smaller than a second distance between the uppermost surface of the fin-shaped region and the upper surface of the substrate;
an insulating pattern in the recess; and
a first gate structure overlying the uppermost surface of the fin-shaped region and a second gate structure overlying an uppermost surface of the insulating pattern.

17. The integrated circuit device of claim 16, wherein the uppermost surface of the insulating pattern is higher than the uppermost surface of the fin-shaped region relative to the upper surface of the substrate.

18. The integrated circuit device of claim 17, wherein uppermost surfaces of the first and second gate structures are coplanar.

19. The integrated circuit device of claim 16, further comprising a source/drain region between the first and second gate structures.

20. The integrated circuit device of claim 19, wherein the source/drain region comprises a stress inducing pattern having a lattice constant different from a lattice constant of the substrate, and an uppermost surface of the stress inducing pattern is higher than the uppermost surface of the fin-shaped region relative to the upper surface of the substrate.
